(19) United States
(12) Patent Application Publication
(10) Pub. No.: US 2026/0143590 A1
(43) Pub. Date: May 21, 2026

(54) CIRCUIT BOARD FOR RECEIVING AT LEAST ONE CONTACT PIN, METHOD FOR CONTACTING A CIRCUIT BOARD AND CIRCUIT

(71) Applicant: BIZLINK INDUSTRY GERMANY GMBH, Roth (DE)

(72) Inventors: Walter KODIM, Stein (DE); Bastian OSTERKAMP, Emstek (DE); Manuel MIKCZINSKI, Wardenburg (DE); Dirk NIEKAMP, Nürnberg (DE)

(21) Appl. No.: 19/128,015

(22) PCT Filed: Sep. 27, 2023
(86) PCT No.: PCT/DE2023/100721

§ 371 Date: May 7, 2025

(30) Foreign Application Priority Data
Nov. 8, 2022 (DE) 10 2022 004 142.1

(51) Int. Cl. H05K 1/11; H05K 1/18; H05K 3/325

(52) U.S. Cl. CPC H05K 1/115; H05K 1/18; H05K 3/325; H05K 2201/10287; H05K 2201/10303; H05K 2201/1059

(57) ABSTRACT

The following abstract will replace all prior versions of the abstract in the A circuit board for receiving at least one contact pin, wherein the circuit board has a circuit board body with a circuit board thickness that is determined along a thickness direction and between a receiving side and a side opposite the receiving side, and the press contact receiving means is orientated along the thickness direction and is designed for receiving the contact pin along the thickness direction and fixing the contact pin by means of contact forces acting radially relative to the thickness direction, wherein the press contact receiving means has a first receiving element that is electrically contacting the circuit board and/or arranged in the first receiving element and/or comprised by the first receiving element, wherein the first receiving element is arranged outside the circuit board thickness on the receiving side and has a receiving opening orientated along the thickness direction for receiving the contact pin.

The invention relates to a circuit board for receiving at least one contact pin according to the preamble of claim 1. Furthermore, the invention relates to a method for contacting a circuit board according to claim 13 and a circuit with a circuit board according to claim 15.

Known circuit boards, which are to be contacted by means of a contact pin, for example by means of a press contact or a number of press contacts or also by means of a twist contact or a number of twist contacts, must have a certain thickness and/or a certain mechanical strength, in particular in a planar direction, to receive the particular contact pin in order not to be permanently damaged by the insertion of the contact pin. Even if no permanent damage occurs, it can happen in the case of circuit boards that are too thin and/or have little mechanical strength and/or stiffness that an appropriate contact pin is not fastened sufficiently securely in the circuit board and/or insufficient contacting takes place. Thin circuit boards of this kind have, e.g., a thickness of preferably maximally up to 0.8 millimeters, in particular of maximally up to 0.5 millimeters.

To reinforce thin circuit boards for the receipt of at least one contact pin, sleeve-like reinforcements must hitherto be inserted, which are laborious to install and cause comparatively high costs. The sleeve-like reinforcements can be, e.g., press-fit sleeves or alternatively so-called vias.

The object of the invention is to improve the state of the art.

The object is achieved by a circuit board for receiving at least one contact pin, wherein the circuit board has a circuit board body with a circuit board thickness, wherein the circuit board thickness is determined along a thickness direction and be-tween a receiving side and a side opposite the receiving side, and the contact pin receiving means is orientated along the thickness direction and the contact pin receiving means is configured to receive the contact pin along the thickness direction and to fix the contact pin by means of contact forces acting radially relative to the thickness direction, wherein the contact pin receiving means has a first receiving body in electrical contact with the circuit board or is arranged in the first receiving body or is comprised by the first receiving body, wherein the first receiving body is arranged outside the circuit board thickness on the receiving side and has a receiving opening orientated along the thickness direction for receiving the contact pin.

By arranging the first receiving body outside the circuit board thickness on the receiving side, an in particular mechanically stable receiving means is created independently of the circuit board body. The first receiving body can thereby be adjusted mechanically to receiving the contact pin. In particular, an insertion of contact pins for contacting particularly thin circuit boards is enabled thereby.

The central idea of the invention here is to arrange the first receiving body outside the circuit board thickness and/or the circuit board body, preferably on the circuit board or under the circuit board, in particular on the receiving side, and thus to create a receiving means specifically coordinated to a contact pin, into which the contact pin can be inserted. Optionally, the first receiving body is in electrical contact with the circuit board, for example with a printed conductor. Alternatively, contacting is formed by the contact pin when the contact pin is arranged in the receiving means.

Let the following terms be explained in this context:

A “circuit board” describes a so-called printed, in particular etched, vapor-deposited or otherwise created circuit, also known as a “printed circuit board”, for example, thus an electromechanical body with printed conductors, for example, for conducting electrical current or electrical signals. A circuit board of this kind usually then carries electrical and/or electronic components, wherein the actual circuit board has a “circuit board body” which fulfils the mechanical basic function of the circuit board. A circuit board body of this kind is produced here, for example, as a composite material, for example from glass fibers and synthetic resin or film.

A “thickness direction” is defined by a surface normal relative to the circuit board body and/or by an orthogonal relative to a two-dimensional orientation of the circuit board body. This thickness direction serves as a geometric reference for an extension of the circuit board body along this thickness direction, which then as maximum extension determines a “circuit board thickness”. In this context, let reference be made to the fact that the orthogonality does not have to be mathematically exact here, but a divergence for technical reasons of up to 10°, for example, is included.

The circuit board thickness is determined here between a “receiving side”, thus a side on which the contact pin is supplied or arranged, and an “opposite side” lying opposite the receiving side.

A “contact pin”, which can be present in different embodiments as a “press contact” or also as a “twist contact”, describes an electrical or electronic contacting element in this context. The contact pin has, e.g., a round, in particular oval or circular cross section. Alternatively, or additionally in sections, the contact pin can have a quadrilateral cross section, preferably a rectangular or square cross section. In particular, the contact pin has a cylindrical, quadratic and/or flat outer contour or shape. The outer contour or shape defines in particular a longitudinal extension and/or surface direction of the contact pin. Optionally, the contact pin can be formed conically along the longitudinal extension and/or the surface direction. Optionally, the contact pin additionally can have elastic elements.

A “press contact” is inserted here, similar to an electric plug, but usually on a smaller scale, into the circuit board body or into a corresponding “contact pin receiving means” into the first receiving body according to the invention and then held by a contact force, in particular pressing, especially substantially orthogonally to the thickness direction inside the press contact receiving means. By means of such a contact pin, electronic components, for example, are fixed on the circuit board or electrical connections are realized, for example for connection cables.

Alternatively or additionally, instead of a press contact, a so-called “twist contact” can be used by analogy. A twist contact of this kind is brought into engagement with the respective receiving body by means of a bayonet-like or toggle-like connection acting frictionally in particular by means of radial contact forces. To this end the contact pin is inserted initially axially along the thickness direction into the respective receiving body and then fixed by means of a rotary movement. Alternatively or additionally, the contact pin can also have a crimp receiving means for receiving a wire, shield, braid or conductor, or can form this. For example, the crimp receiving means can be crimped on a press contact directly upon pressing the press contact in, so as to be able to undertake two work steps in a common work step.

The “contact pin receiving means” is implemented to this end as a hole or opening, for example, or also as a position provided for a contact pin on the circuit board. For example, the contact pin receiving means has a cross section corresponding to the contact pin and/or suitable for this. The contact pin receiving means preferably has a round, in particular oval or circular cross section, or a quadrilateral, in particular rectangular or square cross section. In particular, the contact pin receiving means is formed conically along its longitudinal extension and/or surface direction. The contact pin is inserted, e.g., with the elastic elements in a radial direction into a part of the circuit board, in particular into the receiving body, especially into the contact pin receiving means and is fixable by contact forces. In the case of the flat contact pin, fixing often takes place here along the longitudinal extension and/or the surface di-rection of the contact pin inside the receiving body of the contact pin receiving means.

A “receiving body” in this context is a geometrical body arranged separately from the circuit board body, which geometrical body has or forms the contact pin receiving means and which is configured and formed for electrical contacting of the contact pin with the circuit board, thus with printed conductors of the circuit board, for example. The arrangement of the receiving body “outside” the circuit board thickness, thus especially outside the volume of the circuit board body, ensures here that the receiving body can even be arranged retrospectively, for example, and specially adapted to the contact pin/pins. According to the invention, the contact pin receiving means here comprises the receiving body or forms this. Alternatively or additionally, the receiving body comprises the contact pin receiving means.

In order particularly to reinforce the circuit board also mechanically by the receiving body, the first receiving body extends over a receiving area of the circuit board along the receiving side of the circuit board body, wherein the first receiving body is connected mechanically to the receiving side, in particular two-dimensionally or at one or multiple points. Mechanical forces of the contact pin can thus be taken up by the first receiving body by means of the mechanical connection to the circuit board.

A “receiving area” describes here the area of influence on the circuit board that is formed by the contact pin and the first receiving body, thus an area in which mechanical forces have to be actively introduced into the circuit board.

In one embodiment, the first receiving body has an inner expansion body extending along the thickness direction, wherein the inner expansion body extends, starting from the receiving side, into the circuit board body and in particular has or continues the receiving opening.

With this “expansion body”, thus an expansion of the receiving body into the circuit board body that is present in particular in the case of an “inner expansion body”, a sleeve-like lengthening, for example, of the receiving body into the circuit board can be created, which produces, for example, a longer friction surface or pressing surface along the thickness direction between the contact pin and the receiving body.

In particular, the inner expansion body is formed here in such a way that the inner expansion body has a cross section in a thickness direction that is equal to or smaller than an inlet opening in the circuit board body, so that the inner expansion body is received in particular radially relative to the thickness direction in the inlet opening in the circuit board body. The inner expansion body can be received in this case in the inlet opening free of force or “with force” or in a force-actuated manner.

An “inlet opening” of this kind is a drill hole, for example, in the circuit board body here. The inlet opening can be formed, e.g., as an elongated hole. The inlet opening has preferably a cross section corresponding to the contact pin and/or suitable for this. The inlet opening has preferably a round, in particular oval or circular cross section, or a quadrilateral, in particular rectangular or square cross section. In particular, the contact pin receiving means is conically formed along its longitudinal extension and/or surface direction.

In a further embodiment, the first receiving body has an outer expansion body ex-tending along the thickness direction, wherein the outer expansion body extends, starting from the receiving side, facing away from the circuit board body and in particular has or continues the receiving opening. By analogy with the previous implementation, in which the inner expansion body extends into the circuit board body, a sleeve-like projection, for example, can be formed by means of the outer expansion body on the circuit board with this embodiment of an outer expansion body, which makes it possible to receive a contact pin with a long receiving surface led through from an opposing side of the circuit board, for example, radially along the thickness direction or, for example, to be able to arrange a component also with the outer expansion body spaced at a distance from the circuit board. Here both embodiments can also be combined with an arrangement of the inner expansion body inside and the outer expansion body outside the circuit board body if this is useful for the geometrical arrangement of an electronic component, for example, or to ensure secure contacting.

In one embodiment, the inner expansion body and/or the outer expansion body is or are narrowed or closed here on an end side facing away from the received contact pin. Thus when inserting and/or receiving a contact pin, for example, microscopic swarf arising or microscopic abraded material can remain in the respective expansion body, so that no contamination of the circuit board arises.

To this end, the inner expansion body and/or the outer expansion body can be filled at least partially with a filler, in particular with an adhesive to increase mechanical strength. The mechanical strength can be increased targetedly with this filler, moreover the binding of swarf or abraded material is easily possible.

In order to be able to undertake through-contacting from one side of the circuit board to the other side of the circuit board also by means of the contact pin, for example, when a component is simultaneously connected by means of the contact pin to the circuit board, a second receiving body is arranged on the opposite side, wherein by means of the first receiving body, the second receiving body and a contact pin received and fixed in the first receiving body and the second receiving body, electrical contacting takes place of the receiving side with the opposite side. Additional elements for through-contacting different sides of the circuit board can thus be eliminated.

In another embodiment, the first receiving body and/or the second receiving body is or are connected by means of welding methods, screwing, pressing methods, riveting methods, gluing and/or by means of soldering methods or another suitable method mechanically and/or electrically to the circuit board body, in particular to printed conductors arranged on the circuit board body.

To be able to produce the first receiving body, the inner expansion body, the outer expansion body and/or the second receiving body efficiently and inexpensively and provide it as a separate component to a circuit board, for example, the first receiving body, the respective expansion body and/or the second receiving body is or are produced by means of punching, by means of bending, by means of deep drawing, by means of an additive method, by means of a metal (pressure die) casting method, by means of metal-coating plastic components and/or by means of machining methods.

In another aspect, the object is achieved by a method for contacting a circuit board according to claim 13. Here the circuit board is provided, the contact pin is positioned along the thickness direction at the receiving opening, so that the contact pin is positioned contact-ready with respect to the receiving opening, and the contact pin is then inserted into the receiving opening, wherein the insertion takes place along the thickness direction and thus the contact pin is received in the receiving opening and is fixed in the receiving opening, in particular by pressing in and/or screwing in. The circuit board can thus be contacted according to the invention by means of a contact pin.

In one embodiment, crimping of the crimp receiving means takes place during insertion of the contact pin. In particular, the crimp receiving means is moved here with respect to the circuit board and crimped by means of the contact to the circuit board.

In another aspect, the object is achieved by a circuit with a circuit board according to one of the previously described embodiments and at least one contact pin, wherein the circuit board is contacted by means of a contact pin or by means of a number of contact pins according to the previously cited method to form the circuit.

A circuit of this kind can be produced efficiently and inexpensively, wherein in particular circuits with circuit boards that are particularly thin and/or have a low mechanical load capacity are contactable.

A “circuit”, which can also be described as a “module”, is an assembly of a circuit board, one or more contact pins and electronic components, for example, wherein such a circuit is in particular a fully or partially functional electronic unit, which is provided for a specific switching or control task, for example.

The invention is explained in greater detail below by means of exemplary embodiments. There is shown:

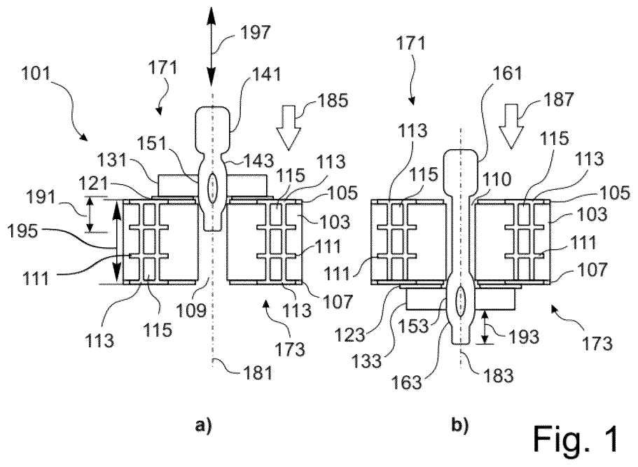

FIG. 1a a schematic representation of a circuit board with a press contact in a cutaway side view,

FIG. 1b a schematic representation of another circuit board with a press contact in a cutaway side view,

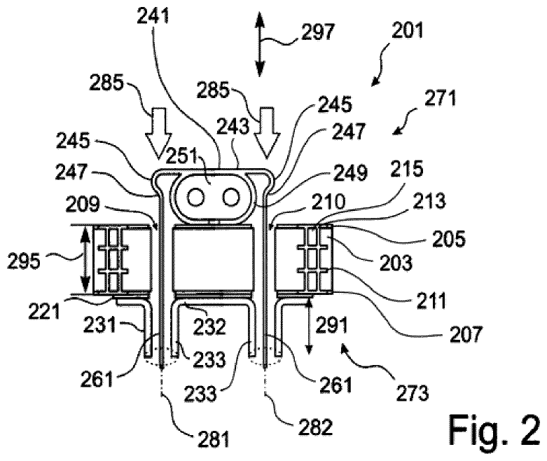

FIG. 2 a schematic representation of a circuit board with a crimp fitting in a cutaway side view, and

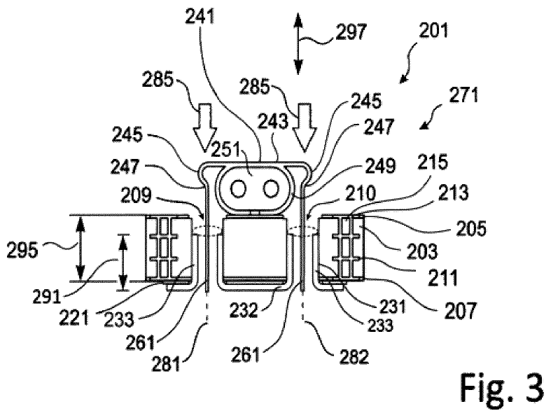

FIG. 3 a schematic representation of a modified circuit board with a crimp fitting in a cutaway side view.

A circuit board 101 is shown by way of example as part of a circuit for an electronic switching module, for example. The circuit 101 has a base body 103 made of a glass fiber composite material on which on an upper side 171, which forms a receiving side, and a lower side 173, which forms an opposite side, a respective printed conductor 105 and 107 is applied in order to be able to conduct electrical current or electrical signals. The printed conductors are made of copper or of other conductive metals and/or metal alloys.

In the base body, an opening 109 is placed along a longitudinal axis 181, which opening serves to insert a press contact 141. The longitudinal axis 181 is arranged here along a thickness direction 197 of the circuit board 101, the circuit board has a thickness 195.

Respective plated-through holes 111 run, starting out from a respective connection 113, between the printed conductor 105 and the printed conductor 107 and thereby contact both printed conductors on both different sides of the circuit board 101 with one another.

On the upper side 171, a receiving means 131, which serves as a receiving body, is attached electrically and mechanically on the printed conductor 105 by means of a contact point 121. The receiving means 131 is formed as a mechanically stable component of electrically conductive metal and receives the press contact 141 at a pressing surface 151 arranged in extension of the opening 109. The press contact 141 has a head 143, wherein the head 143 is deformable radially relative to the longitudinal axis 181. By inserting the press contact 141 along the longitudinal axis 131 via press path 185 along the thickness direction 197, the press contact is fastened and fixed non-positively along the pressing surface 151 in the receiving means 131. Electrical contacting of the press contact 141 via the receiving means 131 with the printed conductor 105 is thus made via a plug-in depth 191.

Analogous thereto (cf. FIG. 1b regarding this), a press contact 161 is received in an opening 110 of the circuit board 101. To this end, the press contact is received in a receiving means 133 on the underside 173 of the circuit board 101. For this the receiving means 133 is arranged by means of a contact point 123 on the printed conductor 107 on the underside 173 of the circuit board 101 and electrically contacted as well as mechanically fixed and attached. The press contact 161 is formed analogous to the press contact 141, has a head 163 and is formed longer than the press contact 141 to reach the receiving means 133 arranged on the underside 173. The press contact 161 is thus attached along a press-in path 187 in the receiving means 133 in a plug-in depth 193.

Let it be mentioned for this purpose that with an arrangement of the receiving means 131 and the receiving means 133 on opposing sides of the opening 209 or 210, for example, contacting of the printed conductor 105 with the printed conductor 107 is enabled with a single press contact formed longer by analogy with the press contact 141 and thus throughplating elements can be saved.

A circuit board 201 (cf. FIG. 2 for this) has by analogy with the previous example a base body 203, a printed conductor 205 on an upper side 271 and a printed conductor 207 on a lower side 273. The circuit board 201 has a thickness 295 along a thickness direction 297. Analogous to the previous example, through-plated holes 211 are provided with connections 213 and fillings 215. By means of a contact point 221, a receiving means 231, which here also serves as a receiving body, is electrically and mechanically contacted and attached on the printed conductor 207. Furthermore, the circuit board 201 has openings 209 and 210. Arranged on the underside 273 along the longitudinal axes 281 and 282 defined by the openings 209 and 210 are a receiving base body 232 and receiving sleeves 233, which serve as expansion bodies, of the receiving means 231. The receiving base body 232 is arranged parallel to the printed conductor 207 on the underside 273, the receiving sleeves 233 extend along the longitudinal axes 281 and 282 away from the circuit board 201, thus along the thickness direction 297. The receiving sleeves 233 are in particular outer expansion bodies.

A crimp fitting 241 is led through the openings 209 and 210. The crimp fitting 241 has an upper part 243, which is arranged parallel to the surface of the printed circuit 201. Limbs 247, which run parallel to the longitudinal axes 281 and 282, then connect orthogonally to the upper part 243 along bends 245. The limbs 247 are led through the openings 209 and 210. A crimp 249, which is arranged between the upper part 243 and the printed conductor 205 internally on the crimp fitting 241, receives a litz wire 251 positively and with electrical contacting. The limbs 247 are then introduced into the receiving sleeves 233 and are received non-positively on pressing surface 261 (into the image plane in FIG. 2) inside the receiving sleeves 233 by analogy with the previous example of the press contacts 241 and 261. The crimp fitting 241 is thus fixed along a press-in path 285 in the plug-in depth 291 in the receiving means 231 and at the same time contacts the litz wire 251 with the printed conductor 205 and the printed conductor 207.

When inserting the crimp fitting 241 along the press-in path 285, crimping of the crimp 249 is implemented or achieved here in that the crimp 249 is led towards the circuit board 201 and pressed together by the contact with the circuit board 201.

A modified circuit board 201 (cf. FIG. 3 for this) differs from the circuit board 201 depicted according to FIG. 2 by the orientation and position of the receiving sleeves 233, which form inner expansion bodies. The receiving sleeves 233 extend as inner expansion bodies into the openings 209, 210 in the base body 203 of the circuit board 201. The receiving sleeves 233 have a cross section which is substantially equal to that of the openings 209, 210. Due to this, the receiving sleeves 233 rest, acted upon by force, on delimiting walls of the openings 209, 210. In an alternative exemplary embodiment, the sleeves can also be received free of force in the openings 209, 210.

### REFERENCE CHARACTER LIST

101 Circuit board

103 Base body

105 Printed conductor

107 Printed conductor

109 Opening

110 Opening

111 Through-plated hole

113 Connection

115 Filling

121 Contact point

123 Contact point

131 Receiving means

133 Receiving means

141 Press contact

143 Head

151 Pressing surface

153 Pressing surface

161 Press contact

163 Head

171 Upper side

173 Lower side

181 Longitudinal axis

183 Longitudinal axis

185 Press-in path

187 Press-in path

191 Plug-in depth

193 Plug-in depth

195 Thickness

197 Thickness direction

201 Circuit board

203 Base body

205 Printed conductor

207 Printed conductor

209 Opening

210 Opening

211 Through-plated hole

213 Connection

215 Filling

221 Contact point

231 Receiving means

232 Receiving base body

233 Receiving sleeve

241 Crimp fitting

243 Upper part

245 Bend

247 Limb

249 Crimp

251 Litz wire

261 Pressing surface

271 Upper side

273 Lower side

281 Longitudinal axis

282 Longitudinal axis

285 Press-in path

291 Plug-in depth

295 Thickness

297 Thickness direction

1. A circuit board for receiving at least one contact pin, wherein the circuit board has a circuit board body with a circuit board thickness, wherein the circuit board thickness is determined along a thickness direction and between a receiving side and an opposite side lying opposite the receiving side and a contact pin receiving means is orientated along the thickness direction and the contact pin receiving means is configured to receive the contact pin along the thickness direction and to fix the contact pin by means of contact forces acting radially relative to the thickness direction, characterized in that the contact pin receiving means has a first receiving body in electrical contact with the circuit board and/or is arranged in the first receiving body and/or is comprised by the first receiving body, where-in the first receiving body is arranged outside the circuit board thickness on the receiving side and has a receiving opening orientated along the thickness direction for receiving the contact pin.

2. The circuit board according to claim 1, characterized in that the first receiving body extends over a receiving area of the circuit board along the receiving side of the circuit board body, is connected mechanically in particular two-dimensionally or at multiple points to the receiving side and by means of the mechanical connection mechanical forces of the contact pin can be taken up by the first receiving body.

3. The circuit board according to claim 1, characterized in that the first receiving body has an inner expansion body ex-tending along the thickness direction, wherein the inner expansion body extends, starting from the receiving side, into the circuit board body and has or continues the receiving opening.

4. The circuit board according to claim 3, characterized in that the inner expansion body has a cross section along the thickness direction that is equal to or smaller than a through opening in the circuit board body, so that the inner expansion body is received in particular radially relative to the thickness direction free of force in the through opening in the circuit board body.

5. The circuit board according to claim 1, characterized in that the first receiving body has an outer expansion body extending along the thickness direction, wherein the outer expansion body extends, starting from the receiving side, facing away from the circuit board body and has or continues the receiving opening.

6. The circuit board according to claim 3, characterized in that the inner expansion body and/or the outer expansion body is or are narrowed or closed on an end side facing away from the received contact pin.

7. The circuit board according to claim 3, characterized in that the inner expansion body and/or the outer expansion body is or are filled at least partially with a filler with an adhesive to in-crease mechanical strength.

8. The circuit board according to claim 1, characterized in that a second receiving body s arranged on the opposite side wherein by means of the first receiving body, the second receiving body and a contact pin received and fixed in the first receiving body and in the second receiving body, electrical contacting takes place of the receiving side with the opposite side.

9. The circuit board according to claim 1, characterized in that the first receiving body and/or the second receiving body is or are connected by means of welding methods, additive methods, screwing, pressing methods, riveting methods, gluing and/or by means of soldering methods mechanically and/or electrically to the circuit board body to printed conductors arranged on the circuit board body.

10. The circuit board according to claim 1, characterized in that the first receiving body, the inner expansion body, the outer expansion body and/or the second receiving body is and are produced by means of punching methods, by means of bending methods, by means of deep drawing methods, by means of an additive method, and/or by means of a machining method.

11. The circuit board according to claim 1, characterized in that a respective contact pin is a press contact with a pressing device acting radially with respect to the respective receiving body and/or that a respective contact pin is a twist contact with a friction-and/or form-fit device acting axially and radially with respect to the respective receiving body.

12. The circuit board according to claim 1, characterized in that the respective contact pin has a crimp receiving means, wherein the crimp receiving means is configured in particular to implement crimping during receiving of the contact pin in the con-tact pin receiving means by deformation of the crimp receiving means by means of the circuit board body.

13. A method for contacting a circuit board according to claim 1 by means of a contact pin with the following steps:
provision of the circuit board for the next method steps,
positioning of the contact pin along the thickness direction so that the contact pin is positioned contact-ready in alignment and/or congruent with the receiving opening,
insertion of the contact pin into the receiving opening along the thickness direction so that the contact pin is received in the receiving opening and is fixed in the receiving opening
so that the circuit board is contacted by means of the contact pin.

14. The method according to claim 13, characterized in that during the insertion of the contact pin crimping of the crimp receiving means is carried out.

15. A circuit with a circuit board according to claim 1 and at least one contact pin wherein to form the circuit, the circuit board is contacted by means of a contact pin or by means of a number of contact pins.
